(19) United States
(12) Patent Application Publication
(10) Pub. No.: US 2025/0085374 A1
(43) Pub. Date: Mar. 13, 2025

(54) Computer-Implemented Method for Gradient Delay Time Correction, Magnetic Resonance Device, Computer Program and Electronically Readable Data Medium

(71) Applicant: Siemens Healthineers AG, Forchheim (DE)

(72) Inventors: Dominik Paul, Bubenreuth (DE); Christian Meixner, Erlangen (DE); Max Müller, Erlangen (DE); Mario Zeller, Erlangen (DE); Michael Köhler, Nuernberg (DE)

(73) Assignee: Siemens Healthineers AG, Forchheim (DE)

(21) Appl. No.: 18/882,940

(22) Filed: Sep. 12, 2024

(30) Foreign Application Priority Data
Sep. 13, 2023 (DE) 10 2023 208 898.3

(51) Int. Cl. G01R 33/565; G01R 33/36; G01R 33/48; G01R 33/56; G01R 33/561

(52) U.S. Cl. CPC G01R 33/56518; G01R 33/3621; G01R 33/4826; G01R 33/5608; G01R 33/5611

(57) ABSTRACT

The disclosure relates to gradient delay time correction of magnetic resonance data. For recording the magnetic resonance data, use is made of a three-dimensional recording technique with linear recording trajectories oriented in different readout directions of a readout plane that is perpendicular to a partition direction. Calibration data is recorded which covers a plurality of partitions in partition direction and which describes readout-direction-dependent shifts, caused by delay effects, of measurement points, e.g. sampled k-space sections in the k-space. Correction data is determined by evaluating the calibration data, and the magnetic resonance data is corrected on the basis of the correction data in order to compensate for the delay effects. The calibration data, which covers a coverage region in partition direction, is recorded in a resolved manner in partition direction, and at least one acceleration technique is applied in the partition direction during the recording of the calibration data.

### CROSS-REFERENCE TO RELATED APPLICATIONS

The present application claims priority to and the benefit of Germany patent application no. DE 10 2023 208 898.3, filed on Sep. 13, 2023, the contents of which are incorporated herein by reference in their entirety.

### TECHNICAL FIELD

The disclosure relates to a computer-implemented method for gradient delay time correction of magnetic resonance data by means of a magnetic resonance device, wherein for the purpose of recording the magnetic resonance data, use is made of a three-dimensional recording technique with linear recording trajectories which are oriented in different readout directions of a readout plane that is perpendicular to a partition direction, wherein in a calibration measurement by means of the magnetic resonance device, calibration data is recorded which covers a plurality of partitions in partition direction and which describes readout-direction-dependent shifts, caused by delay effects, of measurement points, in particular sampled k-space sections, in the k-space, correction data is determined by evaluating the calibration data, and the magnetic resonance data is corrected on the basis of the correction data in order to compensate for the delay effects.

### BACKGROUND

Magnetic resonance imaging has become a standard imaging modality, particularly in the medical field. While recording trajectories which allow Cartesian sampling of the k-space are commonplace and routinely used, non-Cartesian recording trajectories are also now being proposed. One advantage of non-Cartesian sampling of the k-space is the lower susceptibility to movement and flow artifacts, particularly in the case of so-called radial sampling methods in which radial recording trajectories, so-called radial spokes, are used which pass through the k-space center at different angles. The k-space center is repeatedly and continuously sampled in this way. Ghosting artifacts are thus avoided. This results for example in a star-shaped sampling model. If a three-dimensional measurement is performed, a so-called stack of stars is produced and partitions, i.e. thin slices, which are sequentially disposed in a partition direction, can be reconstructed. The plane which is perpendicular to the partition direction and in which the recording trajectories are arranged in the shape of a star is referred to as a readout plane in the same way as other three-dimensional radial sampling models. The axes of an orthogonal coordinate system spanning the readout plane can be referred to as x- and y-axes, the partition direction then being defined by a z-axis. These axes can correspond to physical gradient directions or gradient axes, though this is not generally the case. Logical gradient axes can then be used.

Eddy currents that are generated by gradient pulses can result in temporally and spatially variable field interferences in magnetic resonance devices. Eddy currents that generate a spatially variable magnetic field in the direction of a readout gradient can have an influence on the actual echo time (TE), which represents the zero crossing of the effective gradient moment in readout direction. Since the generated eddy currents are generally dependent on the direction of the gradient pulse which generates them, they can also modify the echo time to varying degrees as a function of the direction of the readout gradient (readout direction).

Other effects can likewise give rise to such delay times, or in general terms delay effects, e.g. imperfections in the magnetic resonance device, in particular the gradient system itself.

In the case of non-Cartesian sampling models which use linear recording trajectories in different readout directions, in particular therefore radial sampling, it is also possible in particular for recording trajectories to occur which are traversed in a manner which is at least substantially contra-oriented, whereby the delay effects cause a problem in respect of the image quality in the readout plane (in-plane). In particular, the delay effects give rise to k-space shifts, such that the measured magnetic resonance data of the k-space is shifted by varying amounts depending on the readout direction or orientation in which the recording trajectory is traversed, such that it exhibits inconsistencies. This can give rise to various artifacts such as ghosting or local signal obliterations. With regard to the recording trajectories which are traversed in a contra-oriented manner (contra-oriented recording trajectories), it should also be noted that these are characterized by opposing polarities of the respective gradient pulses.

### SUMMARY

It has therefore been proposed to apply a delay time correction (DTC) in which corresponding correction data, obtained from calibration data, is averaged in partition direction or is calculated solely for the central partition.

In this case, the determination of the correction data and the derivation of corresponding correction values, e.g. k-space shifts and/or delay times (DT), are based on a recording of calibration data which describes these delay effects, e.g. k-space shifts. It has therefore been proposed e.g. to measure contra-oriented recording trajectories in at least two readout directions, e.g. exactly two readout directions, as calibration data in a calibration measurement. The two readout directions can describe the base of a Cartesian coordinate system and correspond to physical and/or logical gradient axes in the readout plane, for example. For each of these calibration readout directions, the gradient pulses are therefore output once with positive and once with negative polarity, a k-space shift which corresponds to the delay time (corresponds to the offset of the actual echo times) between the calibration scans with different polarity being determined for each calibration readout direction. Using this correction data and a mathematical correlation, k-space shifts (or delay times) can be derived for any readout directions in the readout plane. For example, it is thus possible to shift the sampled k-space sections of the magnetic resonance data within the context of the correction in such a way that a consistent overall image is produced, e.g. before a Cartesian re-gridding.

An article by Tess Armstrong et al., “Free-Breathing Liver Fat Quantification Using a Multiecho 3D Stack-of-Radial-Technique”, Magn. Reson. Med. 79 (2018), Pages 370-382, examines the possibility of fat quantification using three-dimensional radial star sampling. For the purpose of correcting delay effects, e.g. gradient imperfections and gradient deviations, it is proposed in this case to model various delays and eddy current effects as an effective gradient delay, and to record opposed calibration spokes at angles of 0 and π, as well as π/2 and 3π/2, and to compare these by means of cross-correlation to determine k-space shifts on the basis of effective gradient delay effects. Averaging is applied along the partition direction. By means of mathematical correlation, k-space shifts for each spoke were determined from the calibration k-space shifts during the recording of the magnetic resonance data, and used for correction.

In an article by K. T. Block and M. Uecker, “Simple Method for Adaptive Gradient-Delay-Compensation in Radial MRI”, Conference Paper ISMRM 2011, Montreal, for the purpose of specifically evaluating pairs of calibration data sets for recording trajectories which run in a contra-oriented manner, it is proposed to fold these relative to the readout direction in order to perform the cross correlation. It is however specifically proposed not to locate the peak of the cross-correlation function but, to achieve greater precision, determine the shift from the rise in the signal phase by means of linear regression. In this way, parts of the Fourier-transformed calibration data sets which lie outside the examination object and therefore have no defined phase are removed from the study.

In this case, the problem arises that additional recording time is required because the calibration data has to be recorded. In procedures routinely used today, the recording of the calibration data requires an additional time of 12 to 18 seconds for the corresponding recording process. If a larger volume of calibration data is required to increase the accuracy or the resolution, for example, this additional time can increase still further.

The object of the disclosure is to specify a possibility for time-efficient and/or high-quality gradient delay correction.

To achieve this object, provision is made for a computer-implemented method, a magnetic resonance device, a computer program, and an electronically readable data medium as described in accordance with the embodiments herein, including those described in the claims.

In an embodiment, provision is made for at least one acceleration technique to be applied in the partition direction during the recording of the calibration data.

For instance, provision can be made for radial spokes, e.g. offset by the golden angle, to be sampled using the recording technique, e.g. for the purpose of generating a stack of stars. As stated in the introduction, radial sampling techniques are already known from the prior art and advantageously result in less sensitivity to movement. If radial spokes through the k-space center are studied, a three-dimensional measurement results in a star-shaped measurement for each partition (stack of stars). Particularly good sampling of the k-space is obtained if the golden angle is present between consecutively measured readout directions or spokes.

According to the disclosure, it is therefore proposed to employ an acceleration technique whenever there is a requirement for calibration data that is resolved in partition direction, in order to limit as far as possible the lengthening of the recording process due to the additional time for recording the calibration data and/or to record in a comparable time window a larger, e.g. having better resolution, volume of calibration data, which allows an improved gradient delay time correction. This means that overall the correction is accelerated and/or a stable set of data is provided for the correction.

This is appropriate e.g. if the correction data is determined and applied in a manner that is dependent on partition direction. In this case, the evaluation of the calibration data for the correction data may require a larger volume of calibration data as a reliable basis, and this can be provided in a sufficiently short time thanks to the acceleration technique.

Concerning this, it was found that as a result of spatially varying eddy currents in partition direction, delay effects can experience a variation over a three-dimensional volume, e.g. a stack of partitions. For example, magnetic resonance devices have been proposed in which hollow lines are used to transport cooling agents for the gradient coils, said hollow lines resulting in highly localized eddy currents which are also relevant in partition direction. If variations of the delay effects, e.g. delay times or k-space shifts, along the partition direction are not taken into consideration, this can also cause reductions in the image quality.

A preferred field of application proposed in the context of the present disclosure is therefore an approach which also takes into consideration the dependency of the artifacts, triggered by delay effects in the gradients, on the partition direction. The correction is therefore preferably provided in a resolved manner in partition direction and therefore applied in a suitably varied manner over the partition direction. To this end, the calibration data is also recorded in a resolved manner in partition direction, and a partition-dependent calculation of the correction data is performed on the basis of this calibration data. In this case, the delay effects comprise at least the field changes resulting from eddy currents, but can also describe further causes in a model of various effects resulting in shifts.

As a result of the additional resolution of the correction in partition direction, it is possible significantly to reduce spatially varying eddy current effects, thereby improving the image quality of the magnetic resonance data or magnetic resonance image data sets reconstructed therefrom. The partition resolution of the artifacts that are caused by gradient delay effects, in particular eddy currents, is addressed and taken into consideration.

The correction is applied to the recorded magnetic resonance data, e.g. before Cartesian re-gridding in the readout plane. Adaptation of a recording protocol, e.g. a magnetic resonance sequence with which the magnetic resonance data is recorded, cannot be partition-specific due to the simultaneous excitation of the three-dimensional volume.

Calibration data is appropriately recorded for different partitions in partition direction. Partition-specific correction data can then be determined for each of these partitions, e.g. using methods which are known and are described in further detail below, and used for the correction. However, as described in greater detail below, the correction data may be provided in such a way that correction values can be determined for the partitions that are used for the magnetic resonance data.

In an embodiment of the present disclosure, provision can be made for reducing the resolution in partition direction in comparison with the measurement of the magnetic resonance data as an acceleration technique, and/or for recording individual slices, these being fewer in number than the partitions recorded for the magnetic resonance data. The first variant here may be particularly advantageous, since it is still possible to measure using the three-dimensional recording technique. This means that the acceleration is more efficient than with multiple separate slice measurements. Therefore provision may be made for reducing the resolution in partition direction so that the calibration data relates to fewer and/or other partitions than the magnetic resonance data.

Such an acceleration technique is advantageous in connection with a correction that is resolved in partition direction. Thus, according to an advantageous development of the present disclosure, for the purpose of determining correction data and/or, if correction values, in particular k-space shifts and/or delay times, are determined from the correction data and applied in the context of correcting the delay effects, correction values for partitions that are not covered in the calibration data, an interpolation and/or extrapolation is effected in partition direction on the basis of at least two adjacent nodes for partitions that are covered in the calibration data. For tests conducted in the context of the present disclosure have shown that correction values, e.g. k-space shifts and/or delay times, which characterize the delay effects in the partition direction have a profile that is suitable, i.e. in particular relatively smooth, for the purpose of interpolation and/or extrapolation. Therefore, if no correction data set is initially available for a partition of the magnetic resonance data, or if correction values can only be specified for other, e.g. adjacent, partitions, it is possible on the basis of nodes directly to determine and provide the appropriate correction data for the partition concerned or the correction value for the partition concerned by means of interpolation and/or extrapolation. In this case, it is preferable to provide the correction data directly as appropriate for the partitions of the magnetic resonance data, since the calibration data is usually determined selectively for specific recording processes.

It should be noted that specific recordings and measurements in the context of correction values or correction data, e.g. k-space shifts and/or delay times, often exhibit points of discontinuity which are not attributable to delay effects, e.g. eddy currents, but are instead caused by local inhomogeneities owing to air effects in the examination object, e.g. the body of a patient, and/or at the transition between parts of the examination object, e.g. between the torso and the arms of a patient. Such discontinuities can be smoothed out effectively by means of the interpolation and/or extrapolation, e.g. with the use of a model function.

In principle, in the context of the present disclosure, a linear interpolation between the nodes is however also possible, at least to some extent. By virtue of the relatively smooth profile, it is possible to assume linearity locally, this already giving excellent results. For more precise corrections, it can nonetheless be effective to perform a model-based interpolation and/or extrapolation, and different models described by model functions can be used for this purpose. This means that provision can specifically be made for the interpolation and/or extrapolation over the nodes to be effected at least to some extent by fitting a model function to the profile of the correction data or the correction values.

In an appropriate embodiment, the model function can be a polynomial of the second or fourth degree. The profiles observed during trials of the present disclosure show that such polynomials are well suited to describing the profile of the correction data or correction values in the partition direction, while at the same time requiring few fit parameters. For example, if the position in the partition direction is designated as z,

$$F ( z ) = {az}^{2} + bz + c$$

can be used as a polynomial of the second degree. In this case, a, b and c are the fit parameters.

$$F ( z ) = {az}^{4} + {bz}^{3} + {cz}^{2} + dz + e$$

can be used as a polynomial of the fourth degree. In this case, a, b, c, d and e are the fit parameters.

In an embodiment, the cited model function, e.g. the model function together with the fit parameters, may be provided as part of the correction data, so that a suitable correction data set can be derived in a simple manner for all required partitions of the magnetic resonance data.

The number of partitions or slices included in the calibration measurement can advantageously be so selected as to result in an overdetermination of the fit parameters of the model function. Specifically, this means that there are more nodes than fit parameters. This can also apply if, for example, in peripheral regions in partition direction, e.g. outside or at the edge of the homogeneity volume of the magnetic resonance device, parts, i.e. partitions or slices, are omitted from the study because fewer reliable measurements may be present there. In this case, the number of remaining partitions or slices which can serve as nodes should therefore be greater than the number of fit parameters. An overdetermination is applicable e.g. in relation to the previously mentioned points of discontinuity, since the discontinuities are addressed up by the intrinsic smoothing effect and therefore the gradient delay time correction is improved.

For example, if seventy-two partitions are assumed for the magnetic resonance data, ten partitions in the calibration data can already be sufficient for the overdetermination for the fit, so that an acceleration of the recording time by a factor of 7.2 is possible. For example, a recording time of approximately 14 seconds can be reduced to a recording time of approximately 2 seconds for the calibration data.

A further discernable effect in the context of the correction data or correction values, i.e. for k-space shifts and delay times for instance, is a drop towards the edges, e.g. a drop in the delay times. This again does not correspond to the actual conditions, but is based on erroneous data from the edge of the homogeneity volume in partition direction, said data occurring e.g. in receive channels of local coils that are positioned in these regions. For instance, objects or parts of the examination object in the outer measuring field, i.e. located outside or at the edge of the homogeneity volume of the magnetic resonance device in partition direction, can therefore result in very high correction values, e.g. k-space deviations and delay times. The reasons for this can be many and diverse, e.g. artifacts in the dimensioning of the calibration data and/or significant spatial variations in the magnetic and gradient fields and in the send and receive profiles at the edge of the homogeneity volume that can be used for imaging. It is evident e.g. that receive channels of local coils assigned to such parts of the examination object can exhibit erroneous behavior accordingly.

In order to counter this effect, if a plurality of receive channels of a local coil arrangement are used during the measurement of the calibration data and the magnetic resonance data, it is possible when determining the correction data and/or the correction values, e.g. in the case of interpolation and/or extrapolation, using at least one exclusion criterion which indicates an erroneousness of the calibration data, e.g. due to a peripheral location in partition direction, to provide for at least part of the calibration data from at least one receive channel to be excluded. As an example, it is thus possible already when determining the correction data to reduce the unwanted effect, so that overcorrections and the like can be avoided or reduced.

For example, by means of an identification condition, e.g. which uses statistical processing of receive channel-specific evaluation values that correspond to correction values, it is possible to identify receive channels which have measurement results that deviate excessively and to ignore said channels when determining the correction data. It is therefore possible to exclude receive channels which provide implausible or erroneous calibration data from the determination of the correction data. In particular, it is possible to remove from the study those receive channels which result in a correction value that deviates significantly from other receive channels, e.g. a significantly deviating k-space deviation and/or a significantly deviating delay time. Such outliers can be identified e.g. via a statistical analysis, e.g. by means of comparison with a standard deviation or a median, in the identification condition. Suitable threshold values in the identification condition can be determined e.g. empirically and/or predetermined on the basis of a theoretical analysis. Such an exclusion of receive channels appropriately takes place before any averaging over the receive channels.

It should also be noted that to at least reduce overcorrections, provision can be made for correction values, e.g. k-space shifts and/or delay times, which can be determined for the receive channels in the context of correcting the delay effects to be limited by means of a lowest permissible minimum value and/or a highest permissible maximum value. A means that can easily be implemented is thereby provided in order to avoid overcorrections. The maximum and/or minimum correction values are limited. In principle, an empirical specification of suitable minimum values and/or maximum values is conceivable in this case. It has however proven advantageous, in the case of receive channel-specific evaluation of the calibration data for the purpose of determining the correction data, to determine receive channel-specific evaluation values, corresponding to correction values, in particular for the calibration readout directions, and to determine the minimum value and/or the maximum value by means of statistical processing of the evaluation values, e.g. to determine the maximum value as an average or median of the evaluation values.

Tests show that the average or the median over all receive channels as a minimum value and/or maximum value, e.g. as a maximum amount of the respective correction direction, already shows clear advantages in respect of the image quality.

In an alternative approach, provision can also be made for the calibration data to be recorded using a whole-body coil of the magnetic resonance device and for the magnetic resonance data to be recorded using a local coil arrangement having a plurality of receive channels. This can also be effective if the whole-body coil (body coil) has a plurality of receive channels from which an average can be taken. The use of the whole-body coil to determine the correction data is advantageous in that the whole-body coil generally has a receive profile which is more homogenous than that of local coil elements. It is thereby possible to avoid or at least reduce artifacts and problems associated with masking or averaging, due to spatially widely varying receive profiles. The correction data determined by means of the whole-body coil can then be applied to the magnetic resonance data of the local coil arrangement.

It is generally possible in appropriate exemplary embodiments, when evaluating the calibration data for the purpose of determining the correction data, e.g. in the case of interpolation and/or extrapolation, to provide for masking of the calibration data to be performed in the position space, in particular in partition direction, to exclude regions that are not covered by a recorded examination object and/or outer parts of the examination object which are situated e.g. at the edge of or outside a homogeneity volume of the magnetic resonance device. Such masking can also have an advantageous effect with regard to negative influences of parts of the examination object that are arranged peripherally in partition direction. For example, it is conceivable in this context to omit larger regions of the examination object in the partition direction, e.g. the arms of a patient, from the study when determining the correction data, to obtain a more reliable set of data. For example, fitting can be effected by excluding outer values, which can be influenced by possibly erroneous or inaccurate measurements, in partition direction in the position space.

It is further conceivable in exemplary embodiments to use a parallel imaging technique, in particular a generalized autocalibrating partially parallel acquisitions (GRAPPA) technique as an acceleration technique. This is however more complex to implement and therefore less preferable, at least in isolation, though it can allow further advantages in respect of the measuring time.

As mentioned above, application of the present disclosure is particularly advantageous if it is required to provide a correction that is dependent on partition direction. For the purpose of specifically determining correction data in this context, provision can be made e.g. to record the calibration data for at least two calibration readout directions, e.g. spanning an orthogonal coordinate system in the readout plane in the k-space, in such a way that a k-space section of the respective readout direction is traversed in contra-oriented calibration recording trajectories. In this case, the calibration data of each calibration readout direction is evaluated for the purpose of determining a k-space shift, this being dependent on the partition in partition direction in the position space, of the calibration recording trajectories in opposing directions for each partition covered by the calibration data in partition direction. The k-space shifts (which correspond directly to the delay time and can also be determined as such) determined thus for the various partitions form the correction data. Therefore, the conventional approach, e.g. in the articles cited in the introduction, may also be used in this preferred exemplary embodiment, but in this case the evaluation takes place individually for every partition of the calibration data. This means that correction data is then present for every partition of the calibration data. If a lower resolution is used or if measurements are only made in discrete slices in partition direction, the correction data can then be extended by means of interpolation and/or extrapolation onto all partitions of the three-dimensional measurement of the magnetic resonance data, in particular by providing the fitted model function.

As an example, it has been shown that measuring along two calibration readout directions is sufficient for the correction, and therefore recording time for the calibration data can already be saved by a corresponding restriction. The calibration readout directions in this case can correspond to e.g. logical gradient axes in the readout plane, e.g. to an x-direction and a y-direction, correspondence to physical gradient axes being conceivable likewise.

In order to determine k-space shifts for further readout directions of the readout plane, which do not correspond to one of the calibration readout directions, the k-space shifts of the calibration readout directions can be geometrically combined according to a mathematical correlation. Suitable formulas are disclosed e.g. in the two articles by Block et al. or Armstrong et al. cited in the introduction.

Specifically, for the purpose of determining the correction data for each calibration readout direction, provision can be made for the calibration data of both contra-oriented calibration recording trajectories in partition direction to be Fourier-transformed for distribution over partitions in the position space, whereupon for each partition of the calibration data, the calibration data profiles for the calibration recording trajectories are cross-correlated in order to determine a shift in the position space, and the k-space shift associated with the greatest correlation is determined.

To allow the assignment to partitions defined in the position space, a Fourier transformation can first take place in partition direction so that the calibration data is then present in a combination space in which it is ideally also possible for the correction to take place as explained in further detail below. Following the distribution of the calibration data over the partitions, the cross-correlation then takes place to determine the k-space shift with greatest correlation. The cross-correlation can be performed here e.g. by mirroring the calibration data profile of one of the directions, determining a cross-correlation function, e.g. by means of folding with Fourier transformation in the calibration readout direction, and specifying the maximum thereof as the k-space shift concerned. It is however particularly preferred, as per e.g. the publication by Block et al. cited above, to determine the shift with greater precision from the rise of the signal phase using linear regression, the evaluation being appropriately limited to the examination object along the calibration readout direction.

For the purpose of correcting the delay effects in the magnetic resonance data, provision can be made in a specific embodiment as follows:
the magnetic resonance data is Fourier-transformed for assignment to partitions in partition direction,
a correction k-space shift is determined from the correction data as a correction value for each readout direction and partition of the magnetic resonance data that is used for recording the calibration data, and
the magnetic resonance data which has been Fourier-transformed in partition direction, in particular before Cartesian re-gridding in the readout plane, is shifted according to the respective correction k-space shifts.

Therefore, the correction likewise can take place in a sort of “intermediate” space in which the Fourier transformation in respect of the partition direction has already been performed and the assignment to partitions of the magnetic resonance data in the position space is therefore possible. The correction can therefore take place in the readout plane (still in the k-space) with a specific correction value, a k-space shift here, per partition/slice.

In addition to the method, the present disclosure also relates to a magnetic resonance device having a control device that is designed to perform the method. All of the explanations concerning the method can be transferred analogously to the magnetic resonance device, such that the advantages previously cited can also be obtained thereby.

The control device may have at least one processor and at least one storage means. Functional components can take the form of hardware and/or software to control the operation of the magnetic resonance device and allow the performance steps of the method and developments thereof. For example, the control device can have a recording unit (sequence unit) to control the recording of the calibration data using the at least one acceleration technique and the magnetic resonance data, as well as other recording processes. The control device can also include an evaluation unit for evaluating the calibration data to determine the correction data, said correction data being determined in particular in a manner that is dependent on partition direction, and a correction unit for correcting, e.g. in a manner that is dependent on partition direction, the magnetic resonance data on the basis of the correction data in order to compensate for the delay effects.

Further functional units and subunits of the cited functional units can be provided to implement developments of the present disclosure. As an example, a calculation subunit can be provided for the purpose of interpolation and/or extrapolation as part of the evaluation or correction unit.

A computer program according to the disclosure can be loaded directly into a storage means of a control device of a magnetic resonance device and has program means such that execution of the computer program on the control device causes the control device to perform the steps of a method according to the disclosure. The computer program can be stored on an electronically readable data medium according to the present disclosure, such that said data medium has control information stored thereon which comprises at least one computer program according to the disclosure and is embodied such that when the data medium is used in a control device of a magnetic resonance device, this is developed to perform a method according to the disclosure. The electronically readable data medium can be a non-transient data medium in particular, e.g. a CD-ROM.

### BRIEF DESCRIPTION OF THE DRAWINGS

Further advantages and details of the present disclosure are derived from the exemplary embodiments described in the following and with reference to the drawings, in which:

FIG. 1 illustrates an example profile of a delay time in partition direction;

FIG. 2 illustrates an example flow diagram of an embodiment of the method according to the disclosure;

FIG. 3 illustrates an example graph for a model function that is fitted to k-space shifts;

FIG. 4 illustrates an example diagram of a magnetic resonance device according to the disclosure; and

FIG. 5 illustrates an example functional structure of a control device of the magnetic resonance device.

### DETAILED DESCRIPTION OF THE DISCLOSURE

Exemplary embodiments of the disclosure for recording magnetic resonance data using a magnetic resonance device are explained in the following. In this case, the magnetic resonance data is recorded using a three-dimensional recording technique in accordance with a recording protocol, e.g. in a single magnetic resonance sequence, in which non-Cartesian sampling of the k-space takes place. The present exemplary embodiments relate to a radial stack-of-stars sampling, in which recording trajectories extending in a readout plane, so-called radial spokes, intersect in the center of the k-space. For the readout time periods assigned to these recording trajectories that extend in different readout directions, gradient pulses are applied in the readout plane, while the spatial resolution in the partition direction perpendicular to the readout plane is effected by means of a phase encoding (outside the readout time period).

As a result of various delay effects relating to the gradients, the recording trajectories can deviate from the recording trajectories originally desired in the design of the magnetic resonance sequence such that the echo times deviate likewise. These delay effects act differently e.g. on k-space sections which run in different orientations along the readout directions, and therefore an inconsistent set of k-space data can be produced overall. While various, e.g. all, delay effects relating to the gradients are usually modeled for an overall time delay correction, the inconsistencies which occur in the case of different readout directions and orientations are primarily caused by eddy currents, which can arise in metallic components of the magnetic resonance device such as hollow lines for cooling agents, for example.

Corrections that average over the partition direction or only study a representative (e.g. central) partition, are already known, in which a correction value, e.g. a k-space shift (e.g. a relative shift of the recording trajectory in the k-space) or a delay time, can be derived from correction data as a function of the readout direction in the readout plane, said correction data having been determined on the basis of calibration data, e.g. for two calibration readout directions forming a right-angled coordinate system in the readout plane.

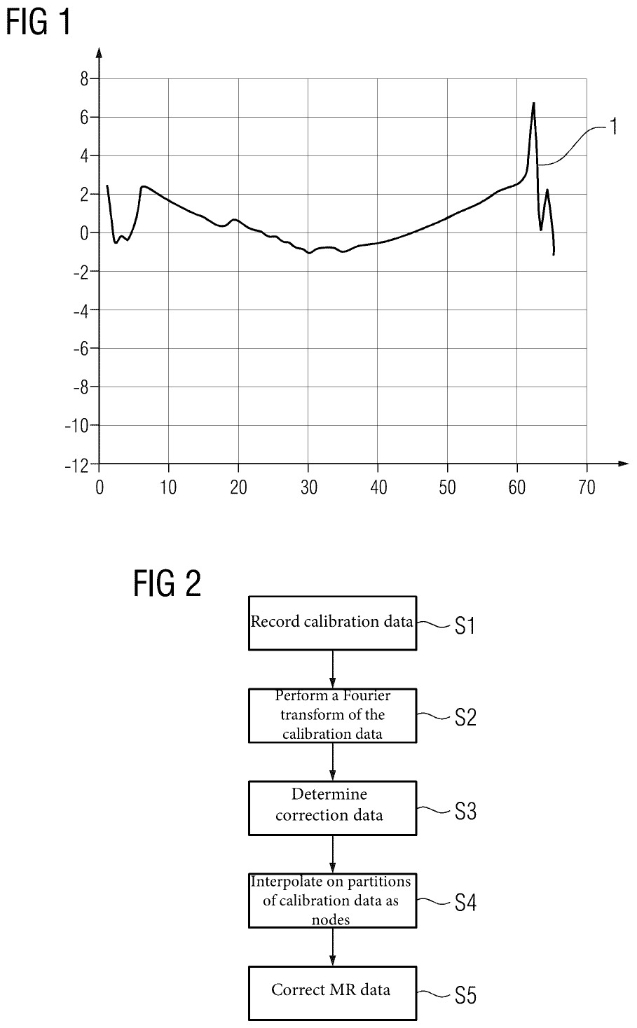

It is however now evident that the delay effects also vary in the partition direction, very significantly in some magnetic resonance devices, consequently resulting in loss of image quality, e.g. artifacts, if the correction only takes place as a function of the readout direction in the readout plane. By way of example, FIG. 1 shows a profile 1 of delay times that occur in partition direction as a result of delay effects for a specific receive channel in the example. In this case, the x-axis shows the location in partition direction in suitable units, while the y-axis shows the delay time in units of the sampling time of the ADC during the recording (dwell time). It can be seen that the delay time varies in the range from approximately −0.5 to 2.5 dwell times. In this context, the drop at the edge (which also corresponds to the edge of the homogeneity volume and can relate to the arms of a patient, for example) is not accurate, but is caused by signal enhancement effects in individual local coil elements of the local coil arrangement.

It is therefore proposed not only to measure the calibration data in a resolved manner in partition direction, but to also specify the correction data from the calibration data in a resolved manner in the partition direction, so that it is possible, e.g. for different partitions of the magnetic resonance data in partition direction, to determine and apply different correction values, in particular k-space shifts and/or delay times, to perform the correction. In the exemplary embodiments shown here, the correction takes place after the recording of the magnetic resonance data, in particular before a Cartesian re-gridding in the readout plane.

In order that the recording of the calibration data, this being resolved in partition direction, does not excessively extend the duration of the overall recording process but nonetheless achieves a high-quality correction, it is proposed to use at least one acceleration technique when recording the calibration data in the partition direction. Specifically, in the case of the exemplary embodiments described herein, a reduced resolution may be used in the partition direction so that fewer and/or other partitions are used in the calibration data than in the recording of the magnetic resonance data. In order nonetheless to obtain correction data that can also be used for the partitions of the magnetic resonance data, it is proposed to interpolate on the basis of the partitions of the calibration data. As an alternative to reducing the resolution in partition direction in the case of three-dimensional measurement, it is also possible selectively to measure specific slices (in a two-dimensional recording technique), e.g. in a plurality of recording steps.

It is also conceivable, e.g. in addition, to achieve an acceleration by means of parallel imaging.

FIG. 2 shows a flow diagram of an exemplary embodiment of the method according to the disclosure. In this case, the calibration data is recorded in a step S1, this being possible on the one hand by means of the local coil arrangement, which is also used to record the magnetic resonance data, but on the other hand is preferably effected by means of a whole-body coil of the magnetic resonance device since this has a more homogenous receive profile, meaning that e.g. the problems of faulty measurements associated with peripheral receive channels can be at least reduced.

For the purpose of recording the calibration data, use is also made of the three-dimensional recording technique that is used for the magnetic resonance data. This means in particular that calibration data is recorded in a resolved manner in partition direction, albeit with lower resolution in partition direction than the magnetic resonance data, to achieve an acceleration of the recording of the calibration data.

As calibration data in the specific exemplary embodiment according to FIG. 2, two calibration readout directions are sampled with opposed orientation, meaning that corresponding contra-oriented calibration recording trajectories are used in respect of a specific k-space section. The calibration readout directions in this case extend over an orthogonal coordinate system in the readout plane and can correspond to physical and/or logical gradient axes, e.g. an x-direction and/or a y-direction. The partition direction then corresponds to the z-direction.

In other words, each of the two calibration readout directions is traversed in both possible orientations, thereby producing a pair of calibration readout trajectories, relative to the coordinate system, with angles of 0° and 180° (π) (e.g. for the x-direction as readout direction) and a further pair of calibration readout trajectories with angles of 90° (π/2) and 270° (3π/2) (e.g. for the y-direction as readout direction).

The recording of the calibration data may e.g. occur immediately before the recording of the magnetic resonance data.

In a step S2, the evaluation of the calibration data begins by means of a Fourier transformation of the calibration data for each calibration recording trajectory along the partition direction. This makes it possible to assign the received calibration data, which is in the readout plane and still present in the k-space, to various partitions in partition direction in the position space. These partitions of the calibration data do not correspond in number and/or position to those of the magnetic resonance data.

In a step S3, the sorted calibration data is evaluated for each partition and for each calibration readout direction in order to determine correction data, specifically k-space shifts, for each calibration readout direction and partition of the calibration data. To this end, the profiles of each of the pairs in the respective calibration readout direction are cross-correlated and the k-space shift with the greatest cross-correlation is ascertained. These k-space shifts with the greatest cross-correlation can then form part of the correction data.

In order to actually perform the cross-correlation, provision can be made for mirroring the calibration data profile of one of the calibration recording trajectories that is traversed in a contra-oriented manner, and then performing a Fourier transformation along the readout direction and determining an intermediate function in the position space by multiplying the one calibration data profile with the other complex-conjugated calibration data profile. While the Fourier transform of this intermediate function forms the cross-correlation function, and it is possible to specify the maximum thereof which is present in the k-space concerned, a more precise approach is preferred which evaluates the rise of the phase, as described in the article cited in the introduction by Block et al. In this context, masking of the calibration data can take place on the examination object itself, in which case parts of the examination object, e.g. the arms of a patient, can also be masked out because the measurement is less accurate in the peripheral region in partition direction.

Following the step S3, k-space shifts are therefore available for every partition (or slice) of the calibration data and for the calibration readout directions.

It should be noted at this point that if the calibration data was not recorded using the whole-body coil, but with the local coil arrangement in a plurality of receive channels, measures can be provided to reduce the described peripheral effects or their influence on the correction, and e.g. to avoid overcorrections. Using an identification condition, for example, erroneous receive channels or receive channels whose calibration data produces a k-space deviation which deviates excessively from the other receive channels can be identified and excluded before the study, e.g. by means of statistical analysis. It is moreover also conceivable when determining the correction data already to define a maximum value and/or a minimum value which must not drop below or be exceeded by correction values, in particular k-space shifts, that are specified for the correction. The minimum value and the maximum value can be determined in a statistical analysis of the k-space shifts of the various receive channels, e.g. limited to non-excluded receive channels, with e.g. the average or the median over the receive channels shown to be a useful maximum or minimum value which can be appended to the correction data.

In order to provide means in the correction data to determine correction values, e.g. correction k-space shifts, for all partitions of the magnetic resonance data, interpolation now takes place in a step S4 on the basis of the partitions of the calibration data as nodes. In the exemplary embodiment illustrated here, a model function is fitted to the profile of the k-space shifts of the partitions of the calibration data in partition direction, as determined in the step S3. In this case, e.g. a polynomial of the second or fourth degree can be used as a model function. Outer k-space shifts which are e.g. too low as a result of being influenced by faulty measurements can preferably be excluded, i.e. using a type of mask which excludes e.g. outer parts of the examination object, e.g. arms of a patient.

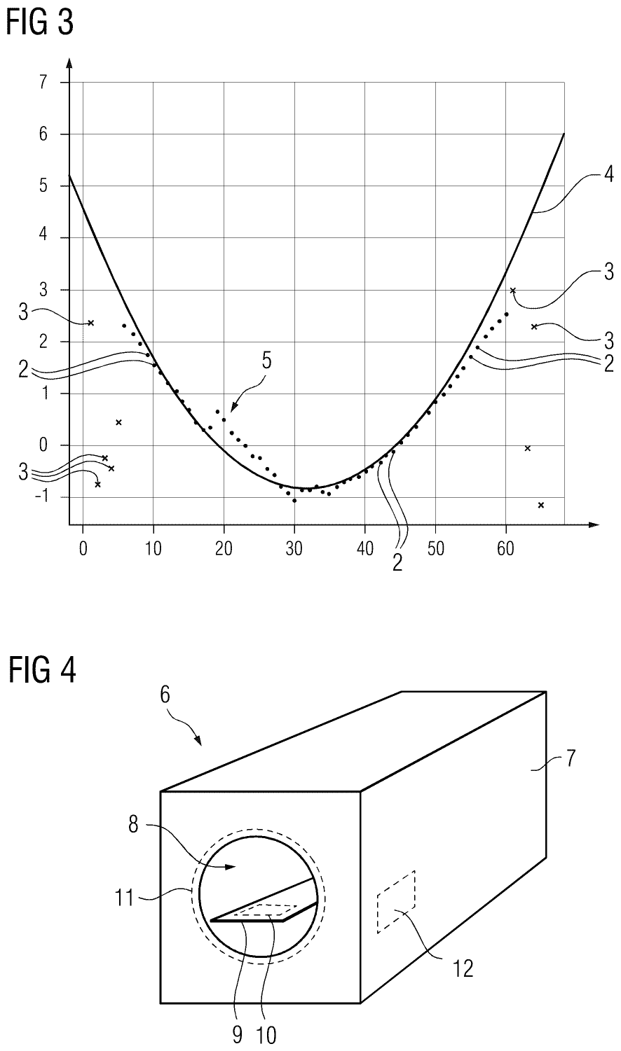

FIG. 3 shows a purely illustrative example, in which the x-axis again shows the location in partition direction in suitable units, while the y-axis shows the delay time in units of the sampling time of the ADC during the recording (dwell time). The profile of the delay time is shown by node measurement points 2, 3 for the different partitions in partition direction. The measurement points 3 represented by “x” are excluded in the course of masking, for example, since they exhibit the erroneous dropping behavior. The model function 4 selected here as a polynomial of the second degree is fitted to the measurement points 2. In particular, the distinct discontinuity in the region 5 is also “smoothed out” thereby.

The fitted model function, e.g. its formula and the fit parameters, can be defined as part of the correction data in the step S4, so that delay times or correction values in general can be specified for any desired partitions of the magnetic resonance data. It is however also possible to evaluate the correction function for the positions of the partitions of the magnetic resonance data and to provide the result as correction data which is specific to these partitions.

The correction of the magnetic resonance data then takes place in the step S5. In order to achieve this, correction values are determined for each partition of the magnetic resonance data and each readout direction of the magnetic resonance data. A correction k-space shift is determined as a correction value for the readout directions by means of a geometric mathematical correlation from the correction data for the corresponding partition of the magnetic resonance data, cf. e.g. the article by Armstrong et al. and Block et al. cited above. The magnetic resonance data that is already Fourier-transformed in the partition direction, and can therefore be assigned to the partitions of the magnetic resonance data, but is still present in the k-space in the readout plane, is adapted on the basis of the correction k-space shifts in such a way that a consistent overall image is produced.

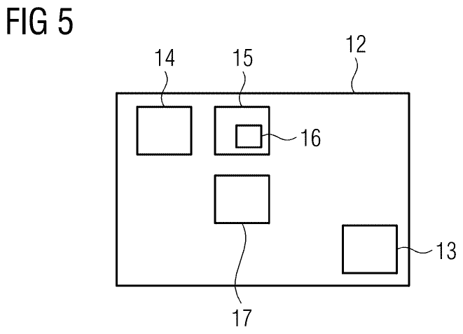

FIG. 4 shows a schematic diagram of a magnetic resonance device 6 according to the disclosure, comprising a main magnet unit 7 with a cylindrical patient receiving region 8 as per known principles. A patient table 9, on which is indicated a local coil arrangement 10 that can be used to record the magnetic resonance data (and also the calibration data if applicable), can be moved into the patient receiving region 8. Surrounding the patient receiving region 8 but not shown in detail here are a gradient coil arrangement and a high-frequency coil arrangement which forms a whole-body coil 11. The calibration data can e.g. be recorded using the whole-body coil 11.

The operation of the magnetic resonance device 6 is controlled by a control device 12 (Also referred to herein as a controller), which is also designed to carry out any of the methods as described herein.

FIG. 5 shows a functional diagram of the structure of the control device 12. In addition to a storage means 13, in which e.g. calibration data, correction data, fit parameters and magnetic resonance data can be stored at least periodically, the control device 12 also has a recording unit 14 which controls the recording operation of the magnetic resonance device generally, e.g. by triggering the gradient coil arrangement and the whole-body coil 11 and/or the local coil arrangement 10 in accordance with a recording protocol, this comprising at least one magnetic resonance sequence. The recording unit 14 is also designed to record the calibration data in the step S1 and to record the magnetic resonance data.

The control device 12 further comprises an evaluation unit 15, in which the calibration data can be evaluated according to the steps S2, S3 and S4 in order to determine the correction data. The evaluation unit comprises a calculation subunit 16 for performing the interpolation according to the step S4.

The correction according to the step S5 can be performed in a correction unit 17.

Although the disclosure is illustrated and described in detail with reference to the preferred exemplary embodiment, the disclosure is not restricted to the examples disclosed herein and other variations may be derived therefrom by a person skilled in the art without departing from the scope of the disclosure.

Independent of the grammatical term usage, individuals with male, female or other gender identities are included within the term.

The various components described herein may be referred to as “units” or “devices.” Such components may be implemented via any suitable combination of hardware and/or software components as applicable and/or known to achieve their intended respective functionality. This may include mechanical and/or electrical components, processors, processing circuitry, or other suitable hardware components, in addition to or instead of those discussed herein. Such components may be configured to operate independently, or configured to execute instructions or computer programs that are stored on a suitable computer-readable medium. Regardless of the particular implementation, such units and/or devices, as applicable and relevant, may alternatively be referred to herein as “circuitry,” “controllers,” “processors,” or “processing circuitry,” or alternatively as noted herein.

What is claimed is:

1. A computer-implemented method for gradient delay time correction of magnetic resonance data via a magnetic resonance device, comprising:
recording the magnetic resonance data using a three-dimensional recording technique with linear recording trajectories that are oriented in different readout directions of a readout plane that is perpendicular to a partition direction;
recording, in a calibration measurement via the magnetic resonance device, calibration data that covers a plurality of partitions in the partition direction and describes readout-direction-dependent shifts, which are caused by delay effects, of measurement points of sampled k-space sections in k-space;
determining correction data by evaluating the calibration data;
correcting the magnetic resonance data based upon the correction data to compensate for the delay effects; and
generating, from the corrected magnetic resonance data, magnetic resonance image data sets,
wherein the calibration data, which covers a coverage region in the partition direction, is recorded in a resolved manner in the partition direction, and
wherein at least one acceleration technique is applied in the partition direction during the recording of the calibration data.

2. The method as claimed in claim 1, wherein the correction data is determined and applied in a manner that is dependent on the partition direction.

3. The method as claimed in claim 1, wherein as the at least one acceleration technique, (i) a resolution in the partition direction is reduced compared with the measurement of the magnetic resonance data, or (ii) individual slices are recorded, which are fewer in number than the plurality of partitions recorded for the magnetic resonance data.

4. The method as claimed in claim 2, further comprising:
determining the correction data by performing an interpolation or extrapolation in the partition direction based upon at least two adjacent nodes for partitions that are covered in the calibration data, and/or
determining, from the correction data, correction values comprising k-space shifts and/or delay times, which are applied for correcting the delay effects, for partitions that are not covered in the calibration data by performing an interpolation or extrapolation in the partition direction based upon at least two adjacent nodes for partitions that are covered in the calibration data.

5. The method as claimed in claim 4, wherein the interpolation is performed at least to some extent between the nodes.

6. The method as claimed in claim 4, wherein the interpolation or extrapolation over the nodes is performed at least to some extent by fitting a model function to a profile of the correction data or the correction values.

7. The method as claimed in claim 6, wherein the model function is a polynomial of a second or a fourth degree.

8. The method as claimed in claim 6, wherein a number of partitions or slices recorded in the calibration measurement is selected to result in an overdetermination of fit parameters of the model function.

9. The method as claimed in claim 4, wherein a plurality of receive channels of a local coil arrangement are used for the measurement of the calibration data and the magnetic resonance data, and
wherein determining the correction data and/or the correction values by performing the interpolation or extrapolation comprises using at least one exclusion criterion that indicates an erroneousness of the calibration data due to a peripheral location in the partition direction by excluding at least part of the calibration data from at least one receive channel.

10. The method as claimed in claim 1, wherein recording the calibration data comprises:
performing an interpolation or extrapolation using a whole-body coil of the magnetic resonance device, and
wherein recording the magnetic resonance data comprises recording the magnetic resonance data using a local coil arrangement having a plurality of receive channels.

11. The method as claimed in claim 1, wherein a parallel imaging technique is used as the at least one acceleration technique.

12. The method as claimed in claim 11, wherein parallel imaging technique comprises a generalized autocalibrating partially parallel acquisitions (GRAPPA) technique.

13. A magnetic resonance device, comprising:
a receiving area configured to receive an object for a magnetic resonance imaging examination; and
a controller configured to perform gradient delay time correction of magnetic resonance data by:
recording the magnetic resonance data using a three-dimensional recording technique with linear recording trajectories that are oriented in different readout directions of a readout plane that is perpendicular to a partition direction;
recording, in a calibration measurement via the magnetic resonance device, calibration data that covers a plurality of partitions in the partition direction and describes readout-direction-dependent shifts, which are caused by delay effects, of measurement points of sampled k-space sections in k-space;
determining correction data by evaluating the calibration data;
correcting the magnetic resonance data based upon the correction data to compensate for the delay effects; and
generating, from the corrected magnetic resonance data, magnetic resonance image data sets,
wherein the calibration data, which covers a coverage region in the partition direction, is recorded in a resolved manner in the partition direction, and
wherein at least one acceleration technique is applied in the partition direction during the recording of the calibration data.

14. An non-transitory computer readable medium having instructions stored thereon that, when executed by a controller of a magnetic resonance device, cause the magnetic resonance device to perform gradient delay time correction of magnetic resonance data by:
recording the magnetic resonance data using a three-dimensional recording technique with linear recording trajectories that are oriented in different readout directions of a readout plane that is perpendicular to a partition direction;
recording, in a calibration measurement via the magnetic resonance device, calibration data that covers a plurality of partitions in the partition direction and describes readout-direction-dependent shifts, which are caused by delay effects, of measurement points of sampled k-space sections in k-space;
determining correction data by evaluating the calibration data;
correcting the magnetic resonance data based upon the correction data to compensate for the delay effects; and
generating, from the corrected magnetic resonance data, magnetic resonance image data sets,
wherein the calibration data, which covers a coverage region in the partition direction, is recorded in a resolved manner in the partition direction, and
wherein at least one acceleration technique is applied in the partition direction during the recording of the calibration data.
